(19) United States
(12) Patent Application Publication
(10) Pub. No.: US 2023/0268312 A1
(43) Pub. Date: Aug. 24, 2023

(54) SOFT TOUCH EUTECTIC SOLDER PRESSURE PAD

(71) Applicant: BAE Systems Information and Electronic Systems Integration Inc., Nashua, NH (US)

(72) Inventors: Peter M. Wallace, Newfields, NH (US); Daniel E. Mendoza, Leominster, MA (US)

(73) Assignee: BAE Systems Information and Electronic Systems Integration Inc., Nashua, NH (US)

(21) Appl. No.: 17/675,600

(22) Filed: Feb. 18, 2022

(51) Int. Cl. H01L 23/00; B23K 1/00; B23K 3/08

(52) U.S. Cl. CPC H01L 24/75; B23K 1/0012; B23K 1/0016; B23K 3/087; H01L 24/81; H01L 24/83; H01L 2224/7532; H01L 2224/75312; H01L 2224/75318; H01L 2224/81203; H01L 2224/81815; H01L 2224/83203; H01L 2224/83815

(57) ABSTRACT

A pressure collet that operably engages with a die in which the pressure collet is configured to land on predetermined positions of the die without damaging said die, a perform, or a heat spreader during a reflow process. The pressure collet further comprises a plate that has a mounting surface and a plurality of contact pads that operably engages with the mounting surface of the plate. The plurality of contact pads is configured to apply pressure to predetermined positions of a die without the mounting surface of the plate contacting the die during a reflow process. The plate of the pressure collet is also formed of a first material and the plurality of contact pads are formed of a second material different than the first material.

### STATEMENT OF GOVERNMENT INTEREST

This invention was made with government support awarded under a contract by a United States federal agency. The government has certain rights in the invention.

### TECHNICAL FIELD

The present disclosure generally relates to a device for assisting in a reflow process. More particularly, the present disclosure relates to a pressure collet used to apply pressure to a die during a reflow process. Specifically, the present disclosure relates to a pressure collet used to apply uniform pressure to a die during a reflow process where the structural configuration of the pressure collet is complementary to and/or matches the structural configuration of the die.

### BACKGROUND

Generally, the reflow soldering process is a widely used method of attaching an integrated circuit (IC) or monolithic microwave integrated circuit (MMIC) die to a mechanical carrier or heat spreader. In one instance, an IC or MMIC may be surfaced mounted to a heat spreader or similar component in a reflow soldering process. During these processes, a thermal conductive material, such as a solder preform, is provided to operably engage the die to the heat spreader. While these solder preforms are suitable for operably engaging the die to the heat spreader, these solder preforms, alone, may not adequately adhere the die to the heat spreader. Such inadequate adhesion between the die and the heat spreader may result in electrical circuitry problems and/or issues when the die operates (e.g., solder flow issues, voids forming between the heat spreader and the die, die sitting at uneven or irregular positions on the heat spreader, etc.).

To combat these issues, a pressure collet or pressure pad may be provided during a reflow soldering process to assist the solder preform in operably engaging a die with a heat spreader. However, a conventional pressure collet has drawbacks when applying pressure to the die to help assist the preform in operably engaging the die with a heat spreader. Generally, the conventional pressure collet may be machined and/or manufactured from various materials to apply pressure to corners or edges of the die during a reflow soldering process. While the conventional collet may apply pressure to the die to prevent movement of the die, the heat spreader, and the preform during a reflow soldering process, this conventional collet may damage and mar the top surface of the die (specifically at the corners of the die) due to the structural configuration of the collet. Moreover, the conventional collet may also damage the top surface of the die due to the hardness of the material pressing down on the thin-film structures of the die (e.g., ceramic, graphite, carbide, and other similar types of materials of the like). Furthermore, the convention collet may create at least one bend in the die and/or preform causing voids and loose connections between the heat spreader and the die resulting in inadequate performance between the heat spreader and the die.

### SUMMARY

The presently disclosed pressure collet for soldering reflow processes provides users of soldering reflow processes with an apparatus for applying a uniform pressure to the die while preventing damage to the die. The disclosed pressure collet may apply uniform pressure to the die at areas proximate to the corners or edges of the die and at areas between a central point of the die and the corners or edges of the die. The disclosed pressure collet may also prevent damage to the die when applying pressure to the die to avoid shifting or movement of the die, the heat spreader, and the preform. As such, the pressure collet disclosed herein addresses some of the inadequacies of previously known techniques and pressure collets for combating against damage to the die and movement of the components during soldering reflow processes.

In one aspect, an exemplary embodiment of the present disclosure may provide a pressure collet. The pressure collet includes a plate having a mounting surface. The pressure collet also includes a plurality of contact pads operably engaged with the mounting surface of the plate. The plurality of contact pads is configured to apply pressure to predetermined positions of a die without the mounting surface of the plate contacting the die during a reflow process.

This exemplary embodiment or another exemplary embodiment may further provide that the plurality of contact pads is operably engaged with the plate via a photodefinable polyimide process. This exemplary embodiment or another exemplary embodiment may further provide that the pressure collet further comprises a first pattern defined by the plurality of contact pads; wherein the pattern is complementary to a second pattern defined by the die to enable the plurality of contact pads to contact the die at the predetermined positions. This exemplary embodiment or another exemplary embodiment may further provide that the pressure collet further comprises a first material forming the plate; and a second material forming each contact pad of the plurality of contact pads, wherein the second material is different than the first material. This exemplary embodiment or another exemplary embodiment may further provide that the first material is a ceramic material; and wherein the second material is a polyimide material. This exemplary embodiment or another exemplary embodiment may further provide that at least one contact pad of the plurality of contact pads applies pressure to a first position of the die at an edge of the die; and at least another contact pad of the plurality of contact pads applies pressure to a second position of the die between a central point of the die and the edge of said die. This exemplary embodiment or another exemplary embodiment may further provide a first set of contact pads of the plurality of the contact pads positioned in a first quadrant of the plate; a second set of contact pads of the plurality of the contact pads positioned in a second quadrant of the plate; a third set of contact pads of the plurality of the contact pads positioned in a third quadrant of the plate; and a fourth set of contact pads of the plurality of the contact pads positioned in a fourth quadrant of the plate; wherein each of the first set of contact pads, the second set of contact pads, the third set of contact pads, and the fourth set of contact pads has an equal number of contact pads. This exemplary embodiment or another exemplary embodiment may further provide that a first set of contact pads of the plurality of the contact pads positioned in a first quadrant of the plate; a second set of contact pads of the plurality of the contact pads positioned in a second quadrant of the plate; a third set of contact pads of the plurality of the contact pads positioned in a third quadrant of the plate; and a fourth set of contact pads of the plurality of the contact pads positioned in a fourth quadrant of the plate; wherein each of the first set of contact pads, the second set of contact pads, the third set of contact pads, and the fourth set of contact pads have a different number of contact pads. This exemplary embodiment or another exemplary embodiment may further provide a first configuration for a first set of contact pads of the plurality of the contact pads; a second configuration for a second set of contact pads of the plurality of the contact pads; a third configuration for a third set of contact pads of the plurality of the contact pads; and a fourth configuration for a fourth set of contact pads of the plurality of the contact pads; wherein at least one of the first configuration, the second configuration, the third configuration, and the fourth configuration is symmetrical to at least another one of the first configuration, the second configuration, the third configuration, and the fourth configuration. This exemplary embodiment or another exemplary embodiment may further provide a first configuration for a first set of contact pads of the plurality of the contact pads; a second configuration for a second set of contact pads of the plurality of the contact pads; a third configuration for a third set of contact pads of the plurality of the contact pads; and a fourth configuration for a fourth set of contact pads of the plurality of the contact pads; wherein at least one of the first configuration, the second configuration, the third configuration, and the fourth configuration is asymmetrical to at least another one of the first configuration, the second configuration, the third configuration, and the fourth configuration.

In another aspect, an exemplary embodiment of the present disclosure may provide a system. The system includes a heat spreader. The system also includes a preform operably engaging with a heat spreader. The system also includes a die operably engaged to the heat spreader via the preform and having a predetermined structural configuration. The system also includes a pressure collet operably engaging with the die, wherein the pressure collet is configured to apply pressure to predetermined positions of the die without damaging said die during a reflow process.

This exemplary embodiment or another exemplary embodiment may further provide that the pressure collet further comprises a plate having a mounting surface; and a plurality of contact pads operably engaged with the mounting surface of the plate; wherein the plurality of contact pads is configured to apply pressure to predetermined positions of a die without the mounting surface of the plate contacting the die during the reflow process. This exemplary embodiment or another exemplary embodiment may further provide that the plurality of contact pads is operably engaged with the plate via a photodefinable polyimide process. This exemplary embodiment or another exemplary embodiment may further provide a first pattern defined by the die; and a second pattern defined by the plurality of contact pads; wherein the second pattern is complementary to the first pattern to enable the plurality of contact pads to contact the die at the predetermined positions. This exemplary embodiment or another exemplary embodiment may further provide that the pressure collet further comprises at least one contact pad of the plurality of contact pads that applies pressure to a first position of the die at an edge of the die; and at least another contact pad of the plurality of contact pads that applies pressure to a second position of the die between a central point of the die and the edge of the die.

In yet another aspect, an exemplary embodiment of the present disclosure may provide a method. The method comprises the steps of introducing a die, wherein the die is configured to operably engage a preform to a heat spreader; introducing a pressure collet to the die, wherein the pressure collet includes a plate and a plurality of contact pads; applying pressure to a first position of the die at an edge of the die via at least one contact pad of the plurality of contact pads; applying pressure to a second position of the die between a central point of said die and the edge of the die via at least another contact pad of the plurality of contact pads; securing the die with the solder preform and the heat spreader, via the plurality of contact pads, during a reflow process; and removing the pressure collet from the die subsequent to the reflow process.

This exemplary embodiment or another exemplary embodiment may further provide that the step of introducing a pressure collet to the die further includes that the plate is formed from a first material and the plurality of contact pads is formed from a second material different than the first material. This exemplary embodiment or another exemplary embodiment may further provide steps of applying pressure to a first quadrant of the die via a first set of contact pads of the plurality of the contact pads; applying pressure to a second quadrant of the die via a second set of contact pads of the plurality of the contact pads; applying pressure to a third quadrant of the die via a third set of contact pads of the plurality of the contact pads; and applying pressure to a fourth quadrant of the die via a fourth set of contact pads of the plurality of the contact pads; wherein each of the first set of contact pads, the second set of contact pads, the third set of contact pads, and the fourth set of contact pads of the plurality of contact pads has an equal number of contact pads. This exemplary embodiment or another exemplary embodiment may further provide steps of applying pressure to first quadrant of the die via a first set of contact pads of the plurality of contact pads, wherein the first set of contact pads is provided in a first configuration on the plate; applying pressure to a second quadrant of the die via a second set of contact pads of the plurality of contact pads, wherein the second set of contact pads is provided in a second configuration on the plate; applying pressure to a third quadrant of the die via a third set of contact pads of the plurality of contact pads, wherein the third set of contact pads is provided in a third configuration on the plate; and applying pressure to a fourth quadrant of the die via a fourth set of contact pads of the plurality of contact pads, wherein the fourth set of contact pads is provided in a fourth configuration on the plate; wherein at least one of the first configuration, the second configuration, the third configuration, and the fourth configuration is symmetrical to at least another one of the first configuration, the second configuration, the third configuration, and the fourth configuration. This exemplary embodiment or another exemplary embodiment may further provide steps of applying pressure to a first quadrant of the die via a first set of contact pads of the plurality of contact pads. wherein the first set of contact pads is provided in a first configuration on the plate; applying pressure to a second quadrant of the die via a second set of contact pads of the plurality of contact pads, wherein the second set of contact pads is provided in a second configuration on the plate; applying pressure to a third quadrant of the die via a third set of contact pads of the plurality of contact pads, wherein the third set of contact pads is provided in a third configuration on the plate; and applying pressure to a fourth quadrant of the die via a fourth set of contact pads of the plurality of contact pads, wherein the fourth set of contact pads is provided in a fourth configuration on the plate; wherein at least one of the first configuration, the second configuration, the third configuration, and the fourth configuration is asymmetrical to at least another one of the first configuration, the second configuration, the third configuration, and the fourth configuration.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 (FIG. 1) is a top plan view of a pressure collet in accordance with an aspect of the present disclosure.

FIG. 2 (FIG. 2) is a sectional view of the pressure collet taken in the direction line 2-2 shown in FIG. 1.

FIG. 3 (FIG. 3) is an exemplary method flow chart.

FIG. 4 (FIG. 4) is another exemplary method flow chart.

Similar numbers refer to similar parts throughout the drawings.

### DETAILED DESCRIPTION

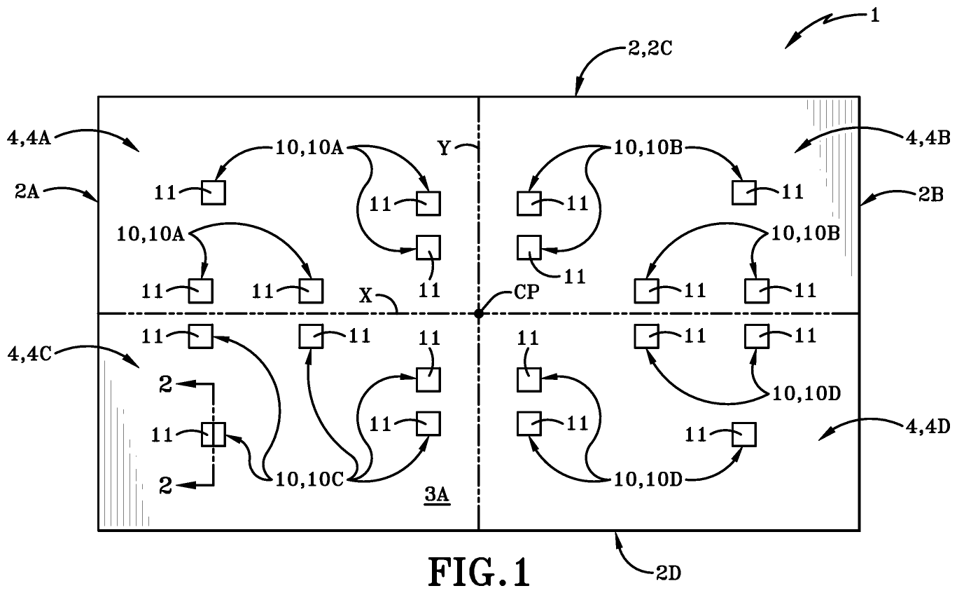

FIG. 1 illustrates a pressure collet 1. As described in more detail below, the pressure collet 1 operably engages with an integrated circuit (IC) or monolithic microwave integrated circuit (MMIC) die (hereinafter “die”) (not illustrated herein) where the pressure collet 1 is configured to apply pressure to predetermined positions on the die without damaging said die during a reflow process. As such, the pressure collet 1 is configured to provide suitable pressure to the die so that the die may operably engage a heat spreader (not illustrated herein) with a solder preform without being damaged during a reflow operation.

It should be understood that the predetermined positions on the die contacted by the pressure collet 1 are areas and/or positions on the die that avoid key components and/or connections from being damaged by the pressure collet 1. In other words, these predetermined positions on the die are areas and/or positions that are enabled to be contacted by the pressure collet 1 while withstanding applied pressure by the pressure collet 1 during solder reflow processing. Such predetermined positions of the die may be edges of the die and positions between the central point of the die and the edges of the die.

The preform discussed herein may be formed of any suitable material that is thermally conductive to operably engage the heat spreader with the die. More particularly, the preform is formed of a metal material that is thermally conductive to operably engage the heat spreader with the die. Specifically, the preform is formed of a gold tin alloy material that is thermally conductive to operably engage the heat spreader with the die.

The integrated circuit discussed herein may be any suitable integrated circuit or MMIC. In one instance, the integrated circuit discussed herein may be a gallium-nitride (GaN) integrated circuit or MMIC. In another instance, the integrated circuit discussed herein may be a gallium-arsenide (GaAs) integrated circuit or MMIC.

Still referring to FIG. 1, the pressure collet 1 may include a substantially rectangular plate 2, however other configurations of plate 2 are possible. When plate 2 is rectangular, the plate 2 includes a first or left side 2A, and an opposing second or right side 2B, and a horizontal axis “X” defined therebetween. The plate 2 also has a first or upper end 2C, an opposing second or lower end 2D, and a vertical axis “Y” defined therebetween. The plate 2 also includes a top surface 3A that is bound by and extends between the upper end 2C and the lower end 2D, and the left side 2A and the right side 2B. The plate 2 may also include a bottom surface 3B that is bound by and extends between the upper end 2C and the lower end 2D, and the left side 2A and the right side 2B. As described in more detail below, the top surface 3A is configured to operably engage with a plurality of photodefineable contact pads 10, and the bottom surface 3B is configured to operably engage with a machine for allowing the pressure collet 1 to apply pressure to the die without damaging said die during a reflow process.

It should be understood that the terms “front,” “rear,” “left,” “right,” “top,” “bottom”, and other directional derivatives used to describe the orientation of pressure collet 1 illustrated in the attached figures should in no way be considered to limit the orientation in which pressure collet 1 may be utilized during a reflow process.

Still referring to FIG. 1, the plate 2 may include a set of quadrants 4. The plate 2 may include a first quadrant 4A in the set of quadrants 4 that extends from the left side 2A to the vertical axis Y and extends from the upper end 2C to the horizontal axis X. The plate 2 may include a second quadrant 4B in the set of quadrants 4 that extends from the right side 2B to the vertical axis Y and extends from the upper end 2C to the horizontal axis X. The plate 2 may include a third quadrant 4C in the set of quadrants 4 that extends from the left side 2A to the vertical axis Y and extends from the bottom end 2D to the horizontal axis X. The plate 2 may include a fourth quadrant 4D in the set of quadrants 4 that extends from the right side 2B to the vertical axis Y and extends from the bottom end 2D to the horizontal axis X. Such use and purpose of each quadrant 4A, 4B, 4C, 4D is described in more detail below. A central point CP of the plate 2 is the location where the horizontal axis X intersects the vertical axis Y.

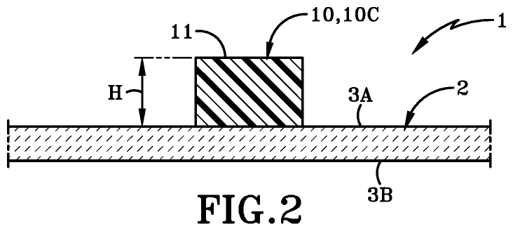

Still referring to FIG. 1, the pressure collet 1 includes the plurality of contact pads 10. Each contact pad of the plurality of contact pads 10 is operably engaged with the top surface 3A of the plate 2. As illustrated in FIG. 2, each contact pad of the plurality of contact pads 10 extends upwardly away from the top surface 3A of the plate 2 when viewed in cross section. Each contact pad of the plurality of contact pads 10 also defines a height “H” that is measured from the top surface 3A of the plate 2 to a top surface 11 of each contact pad of the plurality of contact pads 10. As such, the top surface 11 of each contact pad of the plurality of contact pads 10 is positioned away from the top surface 3A of the plate 2 due to the height “H” of each contact pad of the plurality of contact pads 10. In one embodiment, every contact pad in the plurality of contact pads 10 has the same height H. However, it is possible to selectively provide differing heights H of the contact pads 10 if required for an application specific usage. The plurality of contact pads 10 is configured to apply pressure to predetermined positions of the die without the plate 2 contacting said die during the reflow process. Specifically, the top surface 11 of at least one contact pad or each contact pad of the plurality of contact pads 10 applies pressure to a predetermined position on the die without the top surface 3A of the plate 2 contacting said die during the reflow process. The plurality of contact pads 10 is also arranged in predetermined pattern where the pattern is complementary to and/or matches a pattern defined by the die such that the plurality of contact pads 10 only contacts the die and the plate 2 is free from contacting said die.

Such configuration between the plurality of contact pads 10 and the die allows the plurality of contact pads 10 to provide a suitable amount of pressure to the die so that the die may operably engage the preform with the heat spreader without damaging said die or other electrical components during a reflow operation. Moreover, such configuration between the plurality of contact pads 10 and the die also prevents the top surface 3A of the plate 2 from contacting the die, the integrated circuit, and the heat spreader during a reflow process. Such prevention of contact by the plate 2 eliminates damage to the die (e.g., cracking surfaces of the die, destroying metallic air bridges formed by the die, etc.), eliminates damage to the preform, eliminates damage to the heat spreader, provides void-free solder bond lines, eliminates bows imparted in the die and/or preform, and other suitable preventions when the plate 2 is free from contacting the die, the preform, and the heat spreader.

As illustrated in FIG. 1, the plurality of contact pads 10 is arranged in the set of quadrants 4 of the plate 2. As illustrated, a first set of contact pads 10A of the plurality of contact pads 10 is operably engaged with the plate 2 inside of the first quadrant 4A. A second set of contact pads 10B of the plurality of contact pads 10 is operably engaged with the plate 2 inside of the second quadrant 4B. A third set of contact pads 10C of the plurality of contact pads 10 is operably engaged with the plate 2 inside of the third quadrant 4C. A fourth set of contact pads 10D of the plurality of contact pads 10 is operably engaged with the plate 2 inside of the fourth quadrant 4D. Each of the first, second, third, and fourth sets of contact pads 10A, 10B, 10C, 10D is arranged in pattern that is complementary to a predetermined pattern defined by the die.

The complementary patterning between the plurality of contact pads 10 and the die is considered advantageous at least because the plurality of contact pads 10 is able to precisely apply pressure to predetermined points on the die without damaging the die when the pressure collet 1 is assisting the die in operably engaging the heat spreader with the preform. The complementary patterning between the plurality of contact pads 10 and the die is also considered advantageous at least because the plurality of contact pads 10 is able to precisely apply pressure to predetermined points on the die by preventing voids on solder bond lines and bows of the perform when the pressure collet 1 is assisting the die in operably engaging the heat spreader with the preform.

As illustrated in FIG. 1, the first set of contact pads 10A, the second set of contact pads 10B, the third set of contact pads 10C, and the fourth set of contact pads 10D are arranged symmetrically with one another on the plate 2. More particularly, the arrangement of first set of contact pads 10A is symmetric with third set of contact pads 10C relative to horizontal axis X. The arrangement of the first set of contact pads 10A is symmetric with the second set of contact pads 10B relative to vertical axis Y. The third set of contact pads 10C is symmetric with the fourth set of contact pads 10D relative to vertical axis Y. The second set of contact pads 10B is symmetric with the fourth set of contact pads 10D relative to horizontal axis X. In other exemplary embodiments, first, second, third, and fourth sets of a contact pads of a plurality of contact pads may be arranged in any suitable orientation with a plate based on various considerations, including the size, shape, and configuration of a die, the predetermined pattern of a die, and other various considerations of the like. In one exemplary embodiment, first, second, third, and fourth sets of a contact pads of a plurality of contact pads are arranged asymmetrically with one another on a plate.

As illustrated in FIG. 1, the first set of contact pads 10A, the second set of contact pads 10B, the third set of contact pads 10C, and the fourth set of contact pads 10D have an equal number of contact pads operably engaged with the plate 2. In other exemplary embodiments, first, second, third, and fourth sets of a contact pads of a plurality of contact pads may be any suitable number of contact pads operably engaged with a plate based on various considerations, including the size, shape, and configuration of a die, the predetermined pattern of a die, and other various considerations of the like. In one exemplary embodiment, each of a first set of contact pads, the second set of contact pads, the third set of contact pads, and the fourth set of contact pads has a different number of contact pads operably engaged with the plate 2.

As provided herein, the plate 2 of the pressure collet 1 is formed of a first material, and the plurality of contact pads 10 of the pressure collet 1 is formed of a second material different than the first material. The second material of the plurality of contact pads 10 is a softer and less abrasive material as compared to the first material that forms the plate 2. Specifically, the first material that forms the plate 2 is a ceramic material, and the second material that forms the plurality of contact pads 10 is a photodefinable polyimide material. Such use of photodefinable polyimide material to from the plurality of contact pads 10 is considered advantageous at least because the polyimide material is able to contact and apply suitable pressure on gold material of the die to help enforce engagement of the die to the preform and the heat spreader without damaging the gold material of the die. Such formation of the plurality of contact pads 10 on the plate 2 is described in more detail below. In other exemplary embodiments, any suitable materials may be used to form a plate and a plurality of contact pads of a solder pressure contact pad where the material of the plurality of contact pads is softer and less abrasive than the material of the plate. Other suitable materials may include other polymers comprising a large network of molecules that consist of many repeat units, that are able to provide excellent thermal stability, mechanical strength, electrical properties, and good chemical resistance. Other suitable materials, like polyimides, may be used provided they provide heat resistance, mechanical strength, and insulative properties. Another exemplary material that may be suitable is a dianhydride which also is able to contact and apply suitable pressure on gold material of the die to help enforce engagement of the die to the heat spreader and the integrated circuit without damaging to such gold material of the die.

As described in more detail below, the plurality of contact pads 10 operably engage with the plate 2 via a photodefinable polyimide process. Such process of operably engaging the plurality of contact pads 10 to the plate 2 is considered advantageous at least because the plurality of contact pads 10 are precisely and accurately engaged with the plate 2 to match the predetermined pattern of the die. Such precision and accuracy prevents the pressure collet 1 from damaging the die when the pressure collet 1 provides force on the die to assist the die in operably engaging the heat spreader with the integrated circuit. In other exemplary embodiments, any suitable technique and/or method may be used to operably engage a plurality of contact pads with a plate that matches and is complementary to the predetermined pattern of the die.

Having described the components of the pressure collet 1, a method of using the pressure collet 1 during a reflow process is described below.

Prior to introducing the pressure collet 1, the die is arranged with the heat spreader and the preform so that the preform may be provide suitable electrical connections between the heat spreader and the die. Once arranged, the pressure collet 1 may be applied to the die along with the heat spreader and the preform.

As the pressure collet 1 is introduced to the die, each contact pad of the plurality of contact pads 10 may be arranged to contact a predetermined position or location on the die. As illustrated in FIG. 1, the plurality of contact pads 10 are arranged in a predetermined pattern, which is complementary to the pattern of the die. Each contact pad of the plurality of contact pads 10 is configured to contact a position on the die between an edge of the die and the central point of the die. As described above, the complementary patterning between the pressure collet 1 and the die allows the pressure collet 1 to apply uniform pressure to the die without damaging said die, the perform, and/or the heat spreader when assisting in the operably engagement between the die, the preform, and the heat spreader. In other words, the pressure collet 1 applies uniform pressure to the die without damaging said die to attach the head spreader, the preform, and the die with one another. While not illustrated herein, at least one contact pad of a plurality of contact pads may contact an edge of a die during a reflow process in combination with at least another contact pad of the plurality of contact pads contacting a position on the die between an edge of the die and the central point of the die.

During the reflow process, the pressure collet 1 applies a uniform pressure to a top surface of the die at predetermined position that will not damage or interfere with connections between the heat spreader and the die created by the preform. The uniform pressure applied by the pressure collet 1 is free from damaging or interfering with air bridges or other circuit connections created by the preform when operably engaging the heat spreader with the die. In other words, the pressure collet 1 applies uniform pressure to the die free from damaging or interfering with air bridges or other circuit connections created by the preform when the preform attaches the heat spreader and the die with one another. More particularly, the height “H” of each contact pad of the plurality of contact pads 10 prevents any portion of the plate 2 from contacting the die as said die operably engages the preform to the heat spreader. Specifically, the height “H” of each contact pad of the plurality of contact pads 10 prevents any portion of the top surface 3A of the plate 2 from contacting the die as said die operably engages the preform to the heat spreader.

Upon conclusion of the reflow process, the pressure collet 1 may be removed from the die once the die has operably engaged the preform to the heat spreader. Additionally, the pressure collet 1 may be used repeatably used for various reflow processes where the pressure collet 1 applies pressure to a die (with a complementary pattern) to allow the die to operably engage the preform with the heat spreader.

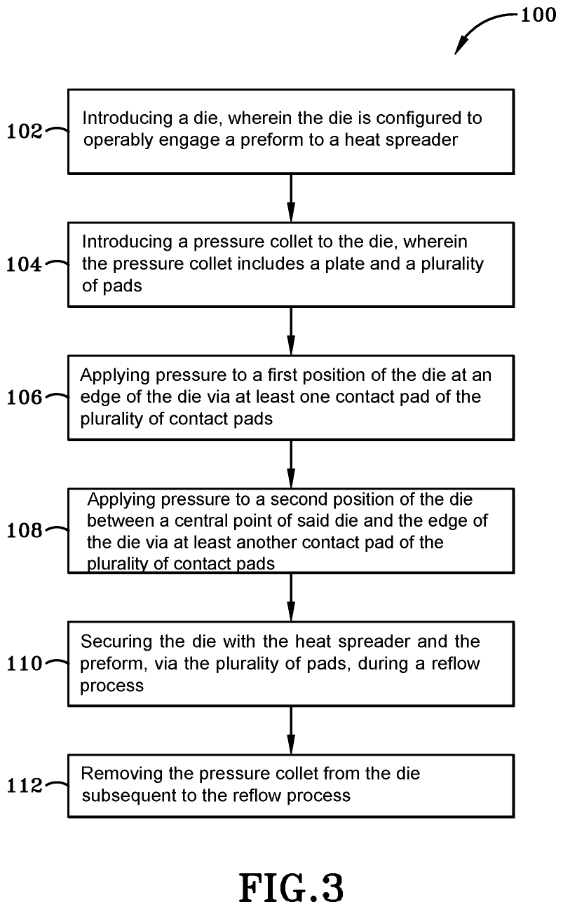

FIG. 3 illustrates a method 100. An initial step 102 of the method 100 comprises introducing a die, wherein the die is configured to operably engage a preform to a heat spreader. Another step 104 comprises introducing a pressure collet to the die, wherein the pressure collet includes a plate and a plurality of contact pads. Another step 106 comprises applying pressure to a first position of the die at an edge of the die via at least one contact pad of the plurality of contact pads. Another step 108 comprises applying pressure to a second position of the die between a central point of said die and the edge of said die via at least another contact pad of the plurality of contact pads. Another step 110 comprises holding the die, via the plurality of contact pads, during a reflow process. Another step 112 comprises removing the pressure collet from the die subsequent to the reflow process.

In other exemplary embodiments, method 100 may include additional steps. An optional step may further comprise that the step of introducing a pressure collet to the die further includes that the plate is formed from of a first material and the plurality of contact pads is formed from a second material different than the first material. Optional steps may further comprise applying pressure to a first quadrant of the die via a first set of contact pads of the plurality of the contact pads; applying pressure to a second quadrant of the die via a second set of contact pads of the plurality of the contact pads; applying pressure to a third quadrant of the die via a third set of contact pads of the plurality of the contact pads; and applying pressure to a fourth quadrant of the die via a fourth set of contact pads of the plurality of the contact pads; wherein each of the first set of contact pads, the second set of contact pads, the third set of contact pads, and the fourth set of contact pads of the plurality of contact pads has an equal number of contact pads. Optional steps may further comprise applying pressure to first quadrant of the die via a first set of contact pads of the plurality of contact pads, wherein the first set of contact pads is provided in a first configuration on the plate; applying pressure to a second quadrant of the die via a second set of contact pads of the plurality of contact pads, wherein the second set of contact pads is provided in a second configuration on the plate; applying pressure to a third quadrant of the die via a third set of contact pads of the plurality of contact pads, wherein the third set of contact pads is provided in a third configuration on the plate; and applying pressure to a fourth quadrant of the die via a fourth set of contact pads of the plurality of contact pads, wherein the fourth set of contact pads is provided in a fourth configuration on the plate; wherein at least one of the first configuration, the second configuration, the third configuration, and the fourth configuration is symmetrical to at least another one of the first, second, third, and fourth configurations. Optional step may further comprise applying pressure to a first quadrant of the die via a first set of contact pads of the plurality of contact pads. wherein the first set of contact pads is provided in a first configuration on the plate; applying pressure to a second quadrant of the die via a second set of contact pads of the plurality of contact pads, wherein the second set of contact pads is provided in a second configuration on the plate; applying pressure to a third quadrant of the die via a third set of contact pads of the plurality of contact pads, wherein the third set of contact pads is provided in a third configuration on the plate; and applying pressure to a fourth quadrant of the die via a fourth set of contact pads of the plurality of contact pads, wherein the fourth set of contact pads is provided in a fourth configuration on the plate; wherein at least one of the first configuration, the second configuration, the third configuration, and the fourth configuration is asymmetrical to at least another one of the first, second, third, and fourth configurations.

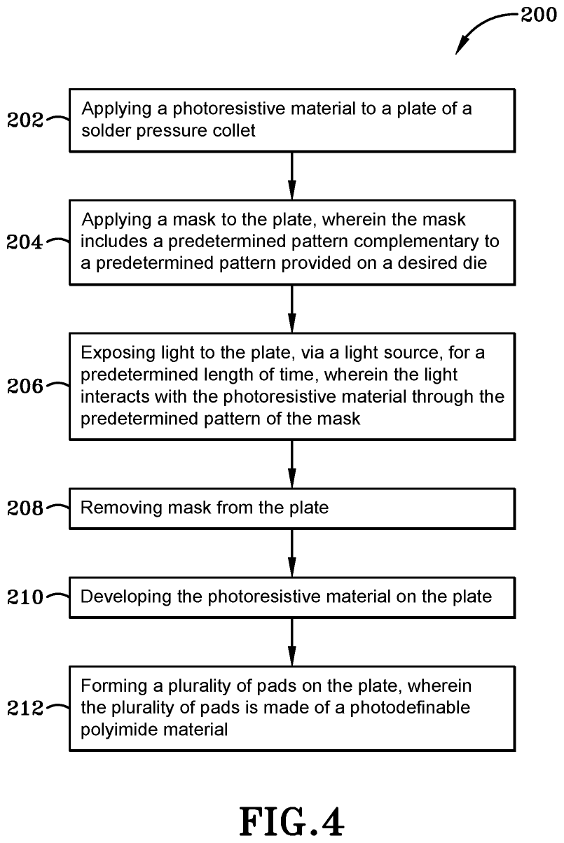

FIG. 4 illustrates another method 200. An initial step 202 of method 200 comprises applying a photoresistive material to a plate of a pressure collet. Another step 204 comprises applying a mask to the plate, wherein the mask includes a predetermined pattern complementary to a predetermined pattern provided on a desired die. Another step 206 exposing light to the plate, via a light source, for a predetermined length of time, wherein the light interacts with the photoresistive material through the predetermined pattern of the mask. Another step 208 comprises removing mask from the plate. Another step 210 comprises developing the photoresistive material on the plate. Another step 212 comprises forming a plurality of contact pads on the plate, wherein the plurality of contact pads is made of a photodefinable polyimide material.

The present disclosure provides a unique application to create tooling used in the recurring process to solder thin GaN semiconductor ICs or MMICs to thermal spreading carriers. This specific tooling creates an ability to increase process yield through process variation improvements as well as reducing the potential for damage to the expensive IC or MMIC devices which can be caused by existing tooling and handling methods. This reduces costs as well as lead times for Super-Regenerative Oscillators (SRO) based MMICs on carriers, ensuring higher levels of availability to microwave module factories that use carrier mounted devices. The lower variation expected should also improve rework and scrap costs, lowering the cost of poor quality.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. A pressure collet, comprising:
a plate having a mounting surface; and
a plurality of contact pads operably engaged with the mounting surface of the plate;
wherein the plurality of contact pads is configured to apply pressure to predetermined positions of a die without the mounting surface of the plate contacting the die during a reflow process.

2. The pressure collet of claim 1, wherein the plurality of contact pads is operably engaged with the plate via a photodefinable polyimide process.

3. The system of claim 1, wherein the pressure collet further comprises:
a first pattern defined by the plurality of contact pads;
wherein the pattern is complementary to a second pattern defined by the die to enable the plurality of contact pads to contact the die at the predetermined positions.

4. The system of claim 1, wherein the pressure collet further comprises:
a first material forming the plate; and
a second material forming each contact pad of the plurality of contact pads, wherein the second material is different than the first material.

5. The pressure collet of claim 4, wherein the first material is a ceramic material; and
wherein the second material is a polyimide material.

6. The pressure collet of claim 1, wherein:
at least one contact pad of the plurality of contact pads applies pressure to a first position of the die at an edge of the die; and
at least another contact pad of the plurality of contact pads applies pressure to a second position of the die between a central point of the die and the edge of said die.

7. The pressure collet of claim 1, further comprising:
a first set of contact pads of the plurality of the contact pads positioned in a first quadrant of the plate;
a second set of contact pads of the plurality of the contact pads positioned in a second quadrant of the plate;
a third set of contact pads of the plurality of the contact pads positioned in a third quadrant of the plate; and
a fourth set of contact pads of the plurality of the contact pads positioned in a fourth quadrant of the plate;
wherein each of the first set of contact pads, the second set of contact pads, the third set of contact pads, and the fourth set of contact pads has an equal number of contact pads.

8. The pressure collet of claim 1, further comprising:
a first set of contact pads of the plurality of the contact pads positioned in a first quadrant of the plate;
a second set of contact pads of the plurality of the contact pads positioned in a second quadrant of the plate;
a third set of contact pads of the plurality of the contact pads positioned in a third quadrant of the plate; and
a fourth set of contact pads of the plurality of the contact pads positioned in a fourth quadrant of the plate;
wherein each of the first set of contact pads, the second set of contact pads, the third set of contact pads, and the fourth set of contact pads have a different number of contact pads.

9. The pressure collet of claim 1, further comprising:
a first configuration for a first set of contact pads of the plurality of the contact pads;
a second configuration for a second set of contact pads of the plurality of the contact pads;
a third configuration for a third set of contact pads of the plurality of the contact pads; and
a fourth configuration for a fourth set of contact pads of the plurality of the contact pads;
wherein at least one of the first configuration, the second configuration, the third configuration, and the fourth configuration is symmetrical to at least another one of the first configuration, the second configuration, the third configuration, and the fourth configuration.

10. The pressure collet of claim 1, further comprising:
a first configuration for a first set of contact pads of the plurality of the contact pads;
a second configuration for a second set of contact pads of the plurality of the contact pads;
a third configuration for a third set of contact pads of the plurality of the contact pads; and
a fourth configuration for a fourth set of contact pads of the plurality of the contact pads;
wherein at least one of the first configuration, the second configuration, the third configuration, and the fourth configuration is asymmetrical to at least another one of the first configuration, the second configuration, the third configuration, and the fourth configuration.

11. A system, comprising:
a heat spreader;
a preform operably engaged with a heat spreader;
a die operably engaged to the heat spreader via the preform and having a predetermined structural configuration; and
a pressure collet operably engaging with the die, wherein the pressure collet is configured to apply pressure to predetermined positions of the die without damaging said die during a reflow process.

12. The system of claim 11, wherein the pressure collet further comprises:
a plate having a mounting surface; and
a plurality of contact pads operably engaged with the mounting surface of the plate;
wherein the plurality of contact pads is configured to apply pressure to predetermined positions of a die without the mounting surface of the plate contacting the die during the reflow process.

13. The system of claim 12, wherein the plurality of contact pads is operably engaged with the plate via a photodefinable polyimide process.

14. The system of claim 12, further comprises:
a first pattern defined by the die; and
a second pattern defined by the plurality of contact pads;
wherein the second pattern is complementary to the first pattern to enable the plurality of contact pads to contact the die at the predetermined positions.

15. The system of claim 12, wherein the pressure collet further comprises:
at least one contact pad of the plurality of contact pads that applies pressure to a first position of the die proximate to an edge of the die; and
at least another contact pad of the plurality of contact pads that applies pressure to a second position of the die between a central point of the die and the edge of the die.

16. A method, comprising steps of:
introducing a die, wherein the die is configured to operably engage a preform to a heat spreader;
introducing a pressure collet to the die, wherein the pressure collet includes a plate and a plurality of contact pads;
applying pressure to a first position of the die at an edge of the die via at least one contact pad of the plurality of contact pads;
applying pressure to a second position of the die between a central point of said die and the edge of the die via at least another contact pad of the plurality of contact pads;
securing the die with the heat spreader and the preform, via the plurality of contact pads, during a reflow process; and
removing the pressure collet from the die subsequent to the reflow process.

17. The method of claim 16, wherein the step of introducing a pressure collet to the die further includes that the plate is formed from a first material and the plurality of contact pads is formed from a second material different than the first material.

18. The method of claim 16, further comprising:
applying pressure to a first quadrant of the die via a first set of contact pads of the plurality of the contact pads;
applying pressure to a second quadrant of the die via a second set of contact pads of the plurality of the contact pads;
applying pressure to a third quadrant of the die via a third set of contact pads of the plurality of the contact pads; and
applying pressure to a fourth quadrant of the die via a fourth set of contact pads of the plurality of the contact pads;
wherein each of the first set of contact pads, the second set of contact pads, the third set of contact pads, and the fourth set of contact pads of the plurality of contact pads has an equal number of contact pads.

19. The method of claim 16, further comprising:
applying pressure to first quadrant of the die via a first set of contact pads of the plurality of contact pads, wherein the first set of contact pads is provided in a first configuration on the plate;
applying pressure to a second quadrant of the die via a second set of contact pads of the plurality of contact pads, wherein the second set of contact pads is provided in a second configuration on the plate;
applying pressure to a third quadrant of the die via a third set of contact pads of the plurality of contact pads, wherein the third set of contact pads is provided in a third configuration on the plate; and
applying pressure to a fourth quadrant of the die via a fourth set of contact pads of the plurality of contact pads, wherein the fourth set of contact pads is provided in a fourth configuration on the plate;
wherein at least one of the first configuration, the second configuration, the third configuration, and the fourth configuration is symmetrical to at least another one of the first configuration, the second configuration, the third configuration, and the fourth configuration.

20. The method of claim 16, further comprising:
applying pressure to a first quadrant of the die via a first set of contact pads of the plurality of contact pads. wherein the first set of contact pads is provided in a first configuration on the plate;
applying pressure to a second quadrant of the die via a second set of contact pads of the plurality of contact pads, wherein the second set of contact pads is provided in a second configuration on the plate;
applying pressure to a third quadrant of the die via a third set of contact pads of the plurality of contact pads, wherein the third set of contact pads is provided in a third configuration on the plate; and
applying pressure to a fourth quadrant of the die via a fourth set of contact pads of the plurality of contact pads, wherein the fourth set of contact pads is provided in a fourth configuration on the plate;
wherein at least one of the first configuration, the second configuration, the third configuration, and the fourth configuration is asymmetrical to at least another one of the first configuration, the second configuration, the third configuration, and the fourth configuration.
